(19) United States
(12) Patent Application Publication
(10) Pub. No.: US 2011/0240362 A1
(43) Pub. Date: Oct. 6, 2011

(54) PRINTED CIRCUIT BOARD AND ELECTRONIC APPARATUS

(76) Inventor: Hiroyuki Matsuo, Oume-shi (JP)

(21) Appl. No.: 12/969,431

(22) Filed: Dec. 15, 2010

(30) Foreign Application Priority Data
Mar. 31, 2010 (JP) 2010-084339

(51) Int. Cl. H05K 1/18; H05K 5/00

(52) U.S. Cl. 174/520; 174/260

(57) ABSTRACT

According to one embodiment, there is provided a printed circuit board including: a board having a first face and a second face opposite to the first face; an electronic component mounted on the first face of the board; a wiring pattern provided on the second face of the board; a land section electrically connected to the electronic component and electrically connected to the wiring pattern; a first slope section continuous with the land section; and a second slope section continuous with the first slope section and the wiring pattern.

### CROSS-REFERENCE TO RELATED APPLICATION(S)

This application is based upon and claims the benefit of priority from Japanese Patent Application No. 2010-084339, filed on Mar. 31, 2010, the entire contents of which are incorporated herein by reference.

### FIELD

Embodiments described herein relate generally to a printed circuit board and an electronic apparatus.

### BACKGROUND

In recent years, as the downsizing of the housings of electronic apparatuses and the saving of the spaces inside the housings have advanced, effective wiring technique for the circuit patterns of printed circuit boards accommodated in such electronic apparatuses are demanded.

For example, JP-H11-054859-A discloses to provide a teardrop wire leading section extending from a land so as to be bilaterally symmetric in shape.

However, in JP-H11-054859-A, the reliability of the teardrop has not been considered sufficiently.

Generally, to provide such teardrop with a land, an area required for the land is increased. For example, in JP-H11-054859-A, to design high density wiring (to decrease the area occupied by the teardrop), the angle of the teardrop is changed (decreased). In this case, if the position of a through hole is displaced, the contact area around the through hole may not be ensured.

### BRIEF DESCRIPTION OF THE DRAWINGS

A general architecture that implements the various feature of the present invention will now be described with reference to the drawings. The drawings and the associated descriptions are provided to illustrate embodiments of the present invention and not to limit the scope of the present invention.

FIG. 1 illustrates an external appearance of a personal computer according to an embodiment.

FIG. 2 illustrates an electronic component mounted on a printed circuit board according to the embodiment.

FIG. 3 sectionally illustrates a semiconductor package according to the embodiment.

FIG. 4 sectionally illustrates a module board according to the embodiment.

FIG. 5 illustrates a face of the printed circuit board according to the embodiment on which a BGA package is not mounted.

FIG. 6 illustrates a state in which a through hole of the printed circuit board according to the embodiment is displaced.

FIG. 7 illustrates an example of the wiring pattern trace of the printed circuit board according to the embodiment.

FIG. 8 illustrates the BGA package mounting area of the printed circuit board according to the embodiment.

FIG. 9 illustrates a modified example of the embodiment.

### DETAILED DESCRIPTION

In general, according to one embodiment, there is provided a printed circuit board including: a board having a first face and a second face opposite to the first face; an electronic component mounted on the first face of the board; a wiring pattern provided on the second face of the board; a land section electrically connected to the electronic component and electrically connected to the wiring pattern; a first slope section continuous with the land section; and a second slope section continuous with the first slope section and the wiring pattern.

An electronic apparatus and a printed circuit board according to the embodiments will be described below referring to the accompanying drawings.

(Configuration of Electronic Apparatus)

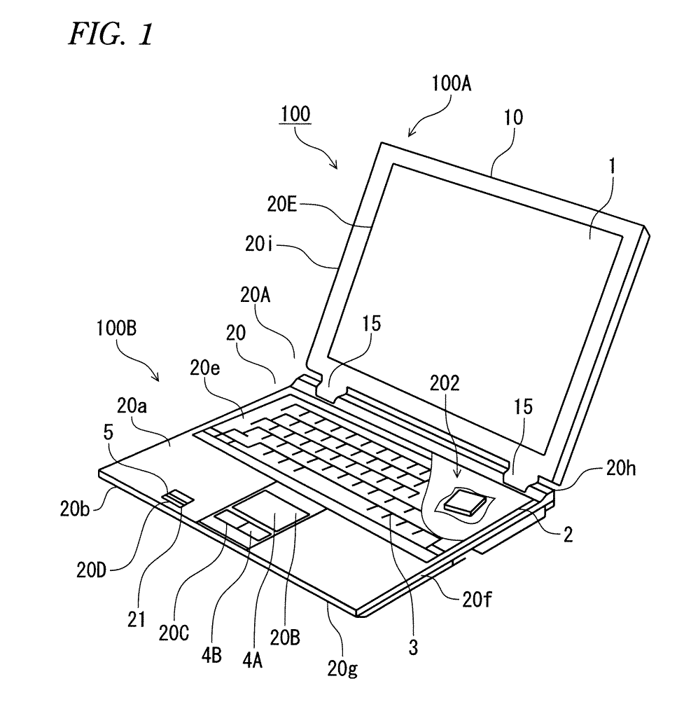

FIG. 1 schematically illustrates an external appearance of an electronic apparatus according to an embodiment. A notebook-sized personal computer is exemplified in the embodiment.

A personal computer 100 (electronic apparatus) according to the embodiment has a display section 100A and a main body section 100B. The display section 100A and the main body section 100B are connected to each other via hinge sections 15 so as to be opened and closed. The main body section 100B has a lower housing 20. The lower housing 20 (housing) accommodates a main body function section 2 for processing information, the main body function section 2 being constructed as a printed circuit board 201 (circuit board) on which electronic components, such as a CPU (central processing unit) and memory devices, are mounted.

The lower housing 20 has an upper face 20a, a bottom face 20b, a left side face 20e, a right side face 20f, a front face 20g and a rear face 20h. A character input section 3, such as a keyboard, for inputting characters and commands, a track pad 4A serving as a pointing device, a determination switch 48 for inputting selection/determination commands, and a fingerprint reading section 5 for user authentication or the like are accommodated in the lower housing 20. Opening sections 20A to 20D are formed in the upper face 20a. Furthermore, a dent section 21 is formed around the opening section 20D on the upper face 20a. The character input section 3 is exposed from the opening section 20A. The track pad 4A is exposed from the opening section 20B. The determination switch 43 is exposed from the opening section 20C. Furthermore, the fingerprint reading section 5 is exposed from the opening section 20D.

The display section 100A has an upper housing 10. An image display section 1 formed of a liquid crystal display panel or the like for displaying characters, images, etc. is accommodated in the upper housing 10. The upper housing 10 has a front face 20i. An opening section 20E is formed in the front face 20i. The image display section 1 is exposed from the opening section 20E.

(Configuration of Printed Circuit Board)

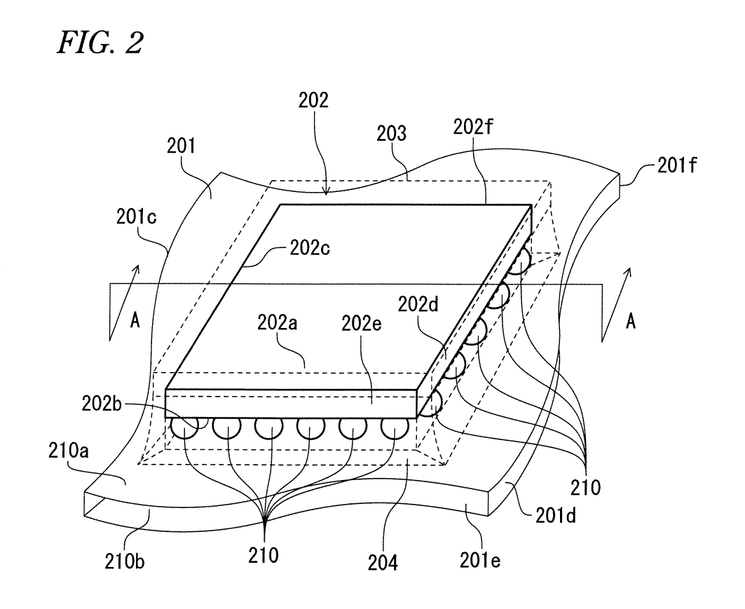

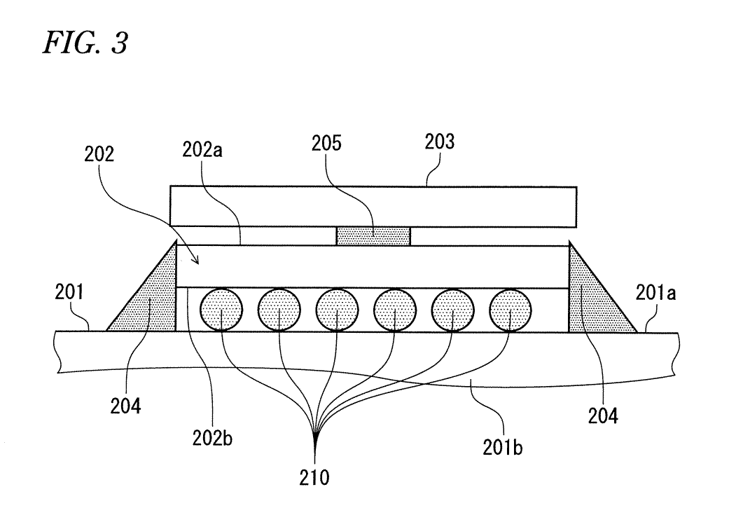

Next, the configuration of an electronic component 202 (semiconductor package) mounted on the printed circuit board 201 according to the embodiment will be described below referring to FIGS. 2 and 3. FIG. 2 illustrates the electronic component 202 mounted on the printed circuit board 201 according to the embodiment. FIG. 3 illustrates a sectional view taken on line A-A of FIG. 2.

A Tape BGA (T-BGA) package (hereafter referred to as a BGA package 202) is exemplified as the electronic component 202 according to the embodiment. In FIGS. 2 and 3, numeral 201 designates the printed circuit board on which various electronic components including the BGA package 202 are mounted, numeral 202 designates the BGA package mounted on the printed circuit board 201, numeral 203 designates a package protection cover for covering the upper face 202a of the BGA package 202, and numeral 204 designates a board joining member for joining the package protection cover 203 to the printed circuit board 201.

The printed circuit board 201 has an upper face 201a and a lower face 201b and side faces 201c to 201f. The upper face 201a and the lower face 201b have circuit patterns. Various electronic components, etc. electrically connected to the circuit patterns are mounted on the upper face 201a and the lower face 201b.

The BGA package 202 has an upper face 202a, a lower face 202b and side faces 202c to 202f. The lower face 202b has plural solder balls 210. The solder balls 210 are joined to the printed circuit board 201, whereby printed wiring formed on the upper face 201a of the printed circuit board 201 is electrically connected to the BGA package 202. In the embodiment shown in FIGS. 2 and 3, the solder balls 210 are melted to join an external junction terminal section (not shown) provided on the lower face 202b of the BGA package 202 to the corresponding electrode pattern on the printed circuit board 201, whereby the BGA package 202 is mounted on the printed circuit board 201.

In the embodiment, the package protection cover 203 is installed at a fixed position on the BGA package 202 so as to cover the BGA package 202 mounted on the printed circuit board 201. The BGA package 202 and the package protection cover 203 are joined to each other using a component joining member 205. The package protection cover 203 is formed of a metal plate having a high thermal conductivity and made of copper, aluminum or stainless steel. The outer size of the package protection cover 203 is larger than the outer size of the mounting face of the BGA package 202. The package protection cover 203 covers the upper face 202a of the BGA package 202, thereby protecting the BGA package 202 against the influence of the thermal deformation and the warping of the printed circuit board 201. The package protection cover 203 not only relaxes the stress applied to the external junction terminal section provided on the package lower face due to the thermal deformation and the warping of the printed circuit board 201, but also releases the heat generated in the semiconductor chip (not shown) inside the BGA package 202 to the outside. A cover installation pattern (not shown) for installing the package protection cover 203 is formed on the printed circuit board 201 at a predetermined position across the mounting position of the BGA package 202.

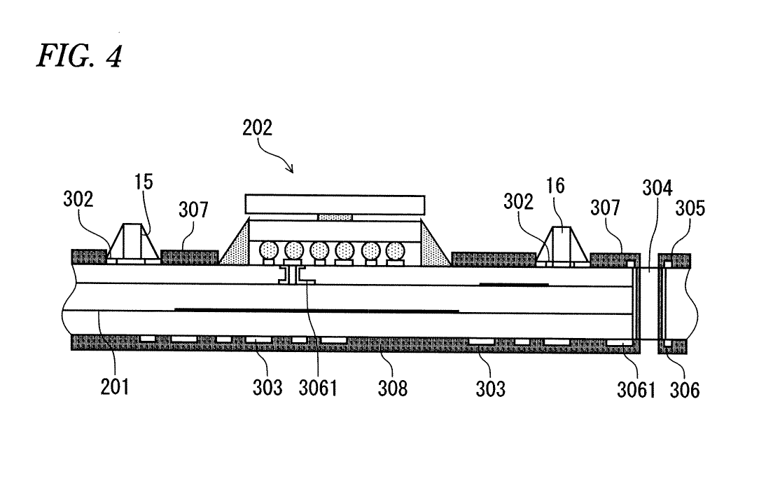

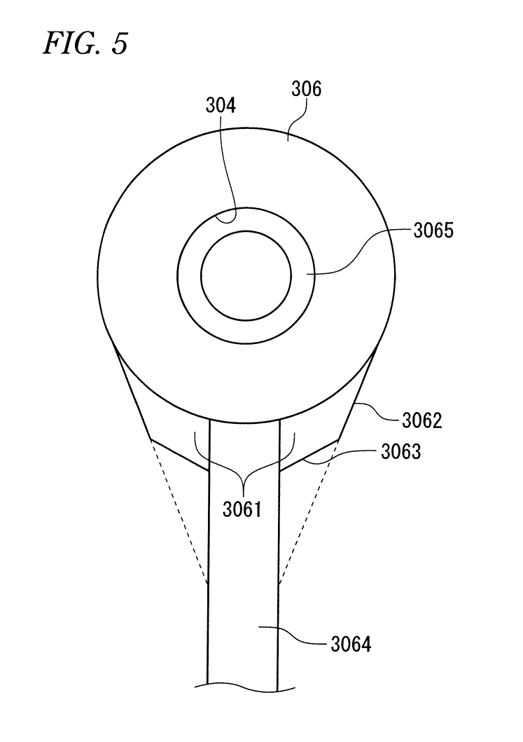

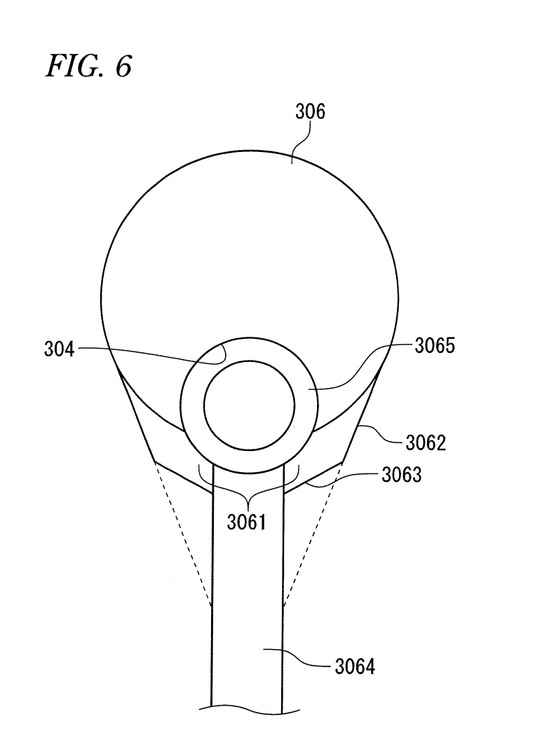

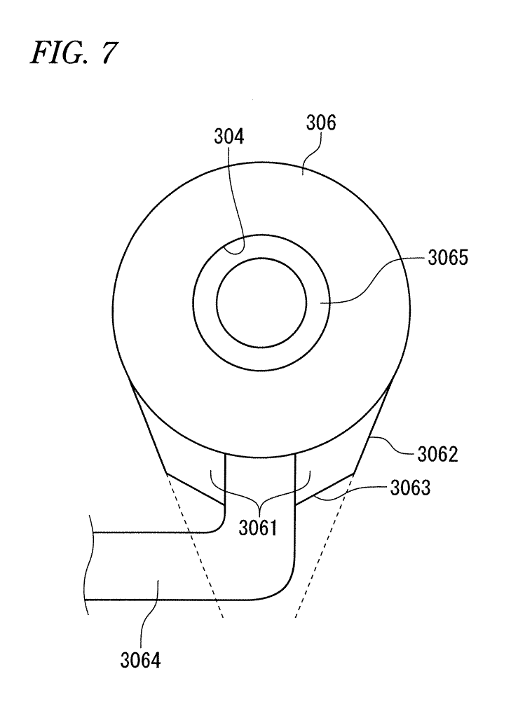

Next, a printed circuit board on which the BGA package 202 according to the embodiment is mounted will be described below. FIG. 4 illustrates a printed circuit board according to the embodiment on which the BGA package 202 is mounted. FIG. 5 illustrates a face of the printed circuit board 201 according to the embodiment on which the BGA package 202 is not mounted. FIG. 6 illustrates a state in which the through hole 304 of the printed circuit board 201 according to the embodiment is displaced. FIG. 7 illustrates an example of the wiring pattern trace 3064 of the printed circuit board 201 according to the embodiment.

As shown in FIG. 4, circuit patterns 302 and 303 are formed on the front and back faces of the printed circuit board 201 made of, for example, glass epoxy resin, respectively. In addition, the through hole 304 is formed in the printed circuit board 201 so as to pass through the printed circuit board 201, and lands 305 and 306 are formed on the front and back faces of the printed circuit board 201, respectively, around the opening sections at both ends of the through hole 304. Resists 307 and 308 serving as protection films are formed on the front and back faces of the printed circuit board 201 having the circuit patterns 302 and 303, respectively. On the front face, the resist 307 is applied to cover at least around the mounting area of the BGA package 202. In the embodiment, the resist 307 has openings for the circuit pattern 302 and for the land 305. On the circuit pattern, active and passive components other than the BGA package 202 are mounted.

On the back face, the resist 308 has a opening for the land 306. Thus, the printed circuit board 201 according to the embodiment has the circuit patterns 302 and 303, the through hole 304 having the lands 305 and 306, and the resists 307 and 308.

The electrodes of the BGA package 202 are connected to the circuit pattern 302 exposed from an opening (mounting area) in the resist 307 on the front face of the printed circuit board 201 via the solder balls 210. The board joining member 204 is disposed between the printed circuit board 201 and the BGA package 202 in the mounting area, and the BGA package 202 is mechanically secured to the printed circuit board 201. Passive components (for example, chip resistors) and 16 are respectively connected to the circuit pattern 302 exposed from the openings of the resist 307 on the front face of the printed circuit board 201.

Furthermore, in the embodiment, a liquid adhesive, such as underfill, can be used as the board joining member 204. Moreover, not only chip resistors but also chip capacitors, for example, can be used as the passive components.

As shown in FIG. 5, the land 306 on the back face of the printed circuit board 201 according to the embodiment is equipped with a teardrop section 3061. The teardrop section 3061 has a first slope section 3062 connected to the land 306 and a second slope section 3063 connected to the first slope section 3062. The second slope section 3063 is connected to a wiring pattern trace 3064 connected to the land 306.

The first slope section 3062 and the second slope section 3063 are provided so as to be bilaterally symmetric with respect to the land 306. Although the second slope section 3063 having a linear shape is exemplified, it is not limited thereto as long as a slope of the second slope section 3063 is gentler than a slope of the first slope section 3062, and the second slope section 3063 may have an arc-shaped slope connected to the first slope section 3062.

As shown in FIG. 5, the first slope section 3062 has a shape formed along imaginary tangent lines extending from the fringe section of the land 306 toward the wiring pattern trace 3064. The slope of the second slope section 3063 is gentler than the slope of the first slope section 3062. The “imaginary tangent lines” are extended from the fringe of the circular-shaped land 306 toward the wiring pattern trace 3064, as indicated by broken lines in FIG. 5. The imaginary tangent lines are used in a teardrop forming step during CAD design. The electrical and physical stability and strength of the teardrop section 3061 can be maintained by smoothly connecting the arc-shaped circumferential fringe of the land 306 to the teardrop section 3061 as described above.

Inside the land 306, the through hole 304 is provided, and a plated section 3065 is plated on an inner surface of the through hole 304 to have a given thickness (in a radial direction of the through hole 304). The second slope section 3063 is located away from the land 306 by a distance greater than the plating thickness of the plated section 3065.

In the printed circuit board 201 having the above-configuration, the connectivity at the first slope section 3062 can be improved. For example, the through hole 304 may be displaced as shown in FIG. 6, in other words, the through hole 304 may be positioned eccentrically with respect to the land 306. In this case, since the printed circuit board 201 according to the embodiment is configured so that the teardrop section 3061 has a bilaterally symmetric shape and so that the second slope section 3063 is located away from the land 306 by a distance greater than a thickness of the plated section 3065, a large connection area can be obtained securely, whereby the reliability of the connection can be maintained.

Since the second slope section 3063 is provided from the middle of the first slope section 3062 in the embodiment as shown in FIG. 7, high density wiring can be attained as compared with the shape of a teardrop formed along the imaginary tangent lines extending from the fringe section of the land 306 toward the wiring pattern trace 3064. That is, for example, as shown in FIG. 7, the wiring direction of the wiring pattern trace 3064 can be changed at a position near the land 306. Hence, the degree of the freedom of designing the wiring pattern trace 3064 can be enhanced while the reliability of the connection is maintained.

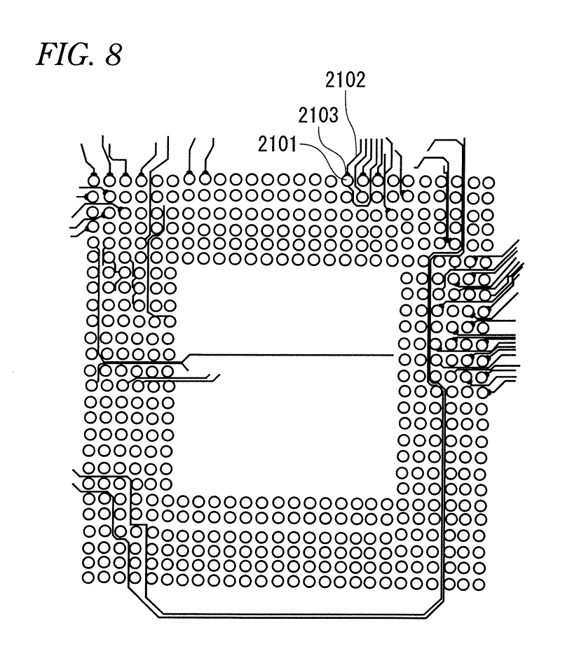

Next, an example configuration of the connection pads of the BGA package 202 to which the embodiment is applied will be described below referring to FIG. 8. FIG. 8 illustrates the BGA package mounting area of the printed circuit board 201 according to the embodiment.

As shown in FIG. 8, plural pads 2101 are provided in the BGA package mounting area of the printed circuit board 201 according to the embodiment. The pads 2101 are respectively connected to the plural solder balls 210 provided on the BGA package 202. The wiring pattern traces 3064 for electrical connection to other mounted components (not shown) extend from some of the pads 2101.

A teardrop section 2103 is provided for a pad 2101 to reinforce the connection portion with a wiring pattern trace 2102. The teardrop section 2103 has a configuration similar to that of the teardrop section 3061 described above.

As shown in FIG. 8, in the embodiment, the connection area between the solder balls 210 and the pads 2101 can be increased while the high density wiring of the BGA package mounting area of the printed circuit board 201 is maintained, whereby the electrical and physical connectivity therebetween can be improved.

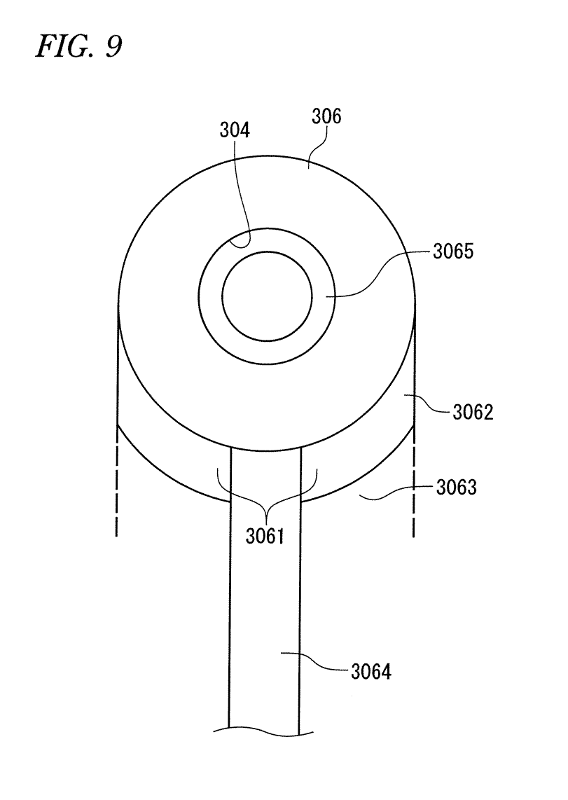

Next, a modified example of the embodiment will be described below referring to FIG. 9. FIG. 9 illustrates a printed circuit board 201 according to the modified example. The configuration of a portable computer 100 according to the modified example is similar to that shown in FIG. 1, except in the following respect.

The modified example differs from the above-mentioned embodiment in the shape of the teardrop section 3061. In the modified example, the first slope section 3062 is provided along the extension direction of a wiring pattern trace, and the second slope section 3063 is provided along the outer fringe of the land 306 to have an arc shape. With this teardrop section 3061, the effects similar to those of the above-mentioned configuration shown in FIGS. 5 to 7 can be obtained, and the allowance for the displacement of the through hole 304 with respect to the land 306 can be increased.

As described above, with the embodiment, the first slope section 3062 connected to the land 306 and the second slope section 3063 connected to the first slope section 3062 and having a slope gentler than that of the first slope section 3062 are provided for the teardrop section 3061 extending from the land 306, whereby the electrical and physical stability and strength of the teardrop section 3061 can be maintained. Furthermore, the teardrop section 3061 according to the embodiment is bilaterally symmetric in shape, whereby the teardrop section 3061 can be designed easily during CAD data operation.

Although a printed circuit board having circuit patterns on both faces is exemplified in the embodiment, the embodiment is not limited to such circuit board. For example, a printed circuit board having a circuit pattern on one face or a multi-layer printed circuit board having inner-layer circuit patterns therein may be used.

The present invention is not limited to the above-mentioned embodiments, but can be embodied by modifying components without departing from the scope of the invention. Various kinds of inventions can be formed by appropriately combining plural components disclosed in the above-mentioned embodiments. For example, some of all the components may be eliminated, and the components of different embodiments may be combined.

According to the embodiments, wiring patterns can be provided at high density while maintaining reliability.

What is claimed is:

1. A printed circuit board comprising:
a board having a first face and a second face opposite to the first face;
an electronic component mounted on the first face of the board;
a wiring pattern provided on the second face of the board;
a land section electrically connected to the electronic component and electrically connected to the wiring pattern;
a first slope section continuous with the land section; and
a second slope section continuous with the first slope section and the wiring pattern.

2. The printed circuit board of claim 1,
wherein a slope of the second slope section is gentler than a slope of the first slope section.

3. The printed circuit board of claim 2,
wherein the land section has a circular shape, and
wherein the first slope section is formed along imaginary tangent lines extending from a fringe of the land section toward the wiring pattern.

4. The printed circuit board of claim 3,
wherein the land section has a through hole section having a plated layer on an inner surface thereof, and
wherein the second slope section is located away from the land section by a distance greater than a thickness of the plated layer.

5. An electronic apparatus comprising:
a housing;
a printed circuit board being accommodated within the housing and having a first face and a second face opposite to the first face;
an electronic component mounted on the first face of the printed circuit board;
a wiring pattern provided on the second face of the printed circuit board;
a land section electrically connected to the electronic component and electrically connected to the wiring pattern;
a first slope section continuous with the land section; and
a second slope section continuous with the first slope section and the wiring pattern.

6. The electronic apparatus of claim 5,
wherein a slope of the second slope section is gentler than a slope of the first slope section.

7. The electronic apparatus of claim 6,
wherein the land section has a circular shape, and
wherein the first slope section is formed along imaginary tangent lines extending from a fringe of the land section toward the wiring pattern.

8. The electronic apparatus of claim 7,
wherein the land section has a through hole section having a plated layer on an inner surface thereof, and
wherein the second slope section is located away from the land section by a distance greater than a thickness of the plated layer.

9. An electronic apparatus comprising:
a housing;
a printed circuit board being accommodated within the housing and having a first face and a second face opposite to the first face;
an electronic component mounted on the first face of the circuit printed board;
a wiring pattern provided on the second face of the circuit printed board;
a land section electrically connected to the electronic component and electrically connected to the wiring pattern;
a first slope section continuous with the land section; and
a second slope section continuous with the first slope section and extended toward the wiring pattern.

10. The electronic apparatus of claim 9,
wherein a slope of the second slope section is gentler than a slope of the first slope section.
